(19) United States
(12) Patent Application Publication
(10) Pub. No.: US 2026/0122790 A1
(43) Pub. Date: Apr. 30, 2026

(54) CIRCUIT BOARD ASSEMBLY, METHOD OF MANUFACTURING CIRCUIT BOARD ASSEMBLY, CAMERA MODULE, PACKAGING METHOD OF CAMERA MODULE, AND ELECTRONIC DEVICE

(71) Applicant: TRIPLE WIN TECHNOLOGY (SHENZHEN) CO. LTD., Shenzhen (TW)

(72) Inventors: CHIEN-LIANG YEH, New Taipei (TW); SHIN-WEN CHEN, New Taipei (TW); JYUN-HONG LU, New Taipei (TW)

(21) Appl. No.: 19/268,762

(22) Filed: Jul. 14, 2025

(30) Foreign Application Priority Data
Oct. 25, 2024 (CN) 202411502582.3

(51) Int. Cl. H05K 3/32; H04N 23/54; H05K 1/18

(52) U.S. Cl. CPC H05K 3/321; H04N 23/54; H05K 1/18; H05K 2201/10128; H05K 2201/10151

(57) ABSTRACT

A method of manufacturing a circuit board assembly includes defining a through hole penetrating a first surface and a second surface of a printed circuit board, the first surface and the second surface facing each other and spaced apart. The method includes placing an image sensor in the through hole, wherein the image sensor is spaced apart from an inner wall of the through hole, and the image sensor is lower than the first surface and higher than or flush with the second surface. The method also includes fixing the image sensor to the printed circuit board, and establishing an electrical connection between the image sensor and the printed circuit board. The circuit board assembly, a camera module and an electronic device including the circuit board assembly, and a packaging method of the camera module are also disclosed.

### FIELD

The subject matter herein generally relates to a circuit board assembly, a method of manufacturing the circuit board assembly, a camera module including the circuit board assembly, a packaging method of the camera module, and an electronic device including the camera module.

### BACKGROUND

Camera modules are widely applied to fields such as mobile phones, laptops, toys, industrial detection, automobiles, and medical equipment. Consumer digital products such as laptops are gradually developing towards being lighter and thinner and towards miniaturization, which requires the camera modules to have a smaller volume. How to reduce a size of the camera modules is a difficult problem to be solved.

### BRIEF DESCRIPTION OF THE DRAWINGS

Implementations of the present technology will now be described, by way of embodiment, with reference to the attached figures.

FIG. 1 is a schematic block diagram of a structure of an electronic device according to an embodiment of the present disclosure.

FIG. 2 is a perspective view of a camera module according to an embodiment of the present disclosure.

FIG. 3 is a cross-section view of the camera module taken along line III of FIG. 2.

FIG. 4 is an exploded view of the camera module of FIG. 2.

FIG. 5 is a flow chart of a method of manufacturing a circuit board according to an embodiment of the present disclosure.

FIG. 6 is a schematic diagram of an exploded structure of the camera module in FIG. 2 when the camera module is manufactured by a die bonder.

FIG. 7 is a flow chart of a packaging method of a camera module according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “connected” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

The present disclosure provides a camera module and an electronic device (such as a laptop computer, a mobile phone, etc.) including the camera module. The camera module has a relatively small size, which meets the demand for miniaturization of electronic devices.

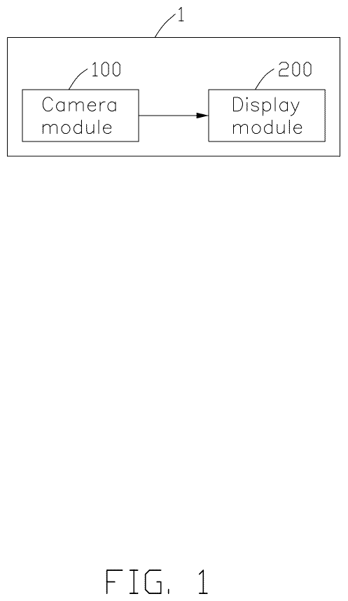

Referring to FIG. 1, an embodiment of a electronic device 1 is illustrated. The electronic device 1 includes a camera module 100 and a display module 200. The camera module 100 is electrically connected to the display module 200. The camera module 100 is configured to generate an image according to an optical signal, and the display module 200 is configured to display the image generated by the camera module 100.

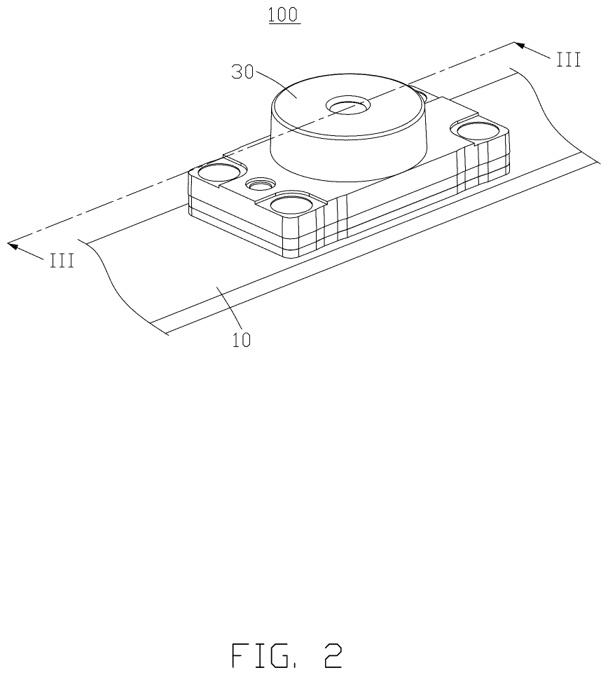

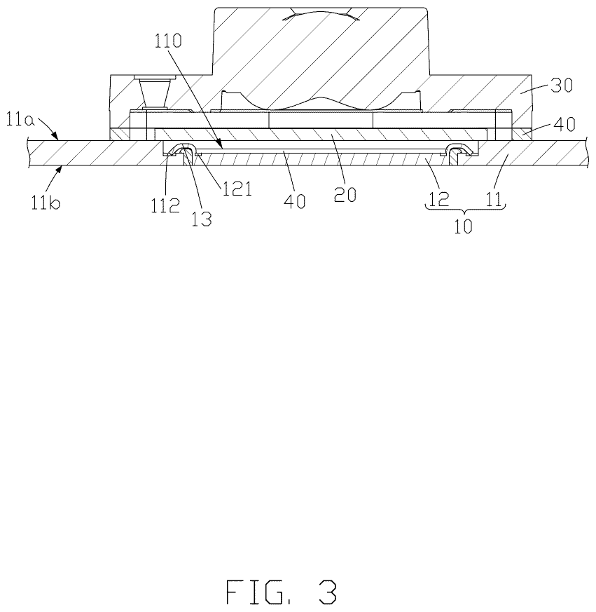

Referring to FIG. 2 and FIG. 3, the camera module 100 includes a circuit board assembly 10, a light filter 20, and a lens assembly 30. The light filter 20 is located between the circuit board assembly 10 and the lens assembly 30, and the light filter 20 and the lens assembly 30 are fixedly connected to the same surface of the circuit board assembly 10. In the camera module 100, the lens assembly 30 is configured to receive and transmit external light. The light filter 20 is located on an optical path of the light emitted by the lens assembly 30, and is configured to filter out part of the light. The other part of the light passes through the light filter 20 and is received by the circuit board assembly 10. The circuit board assembly 10 is configured to generate an image according to the other part of the light. The display module 200 is electrically connected to the circuit board assembly 10, and is configured to display the image generated by the camera module 100.

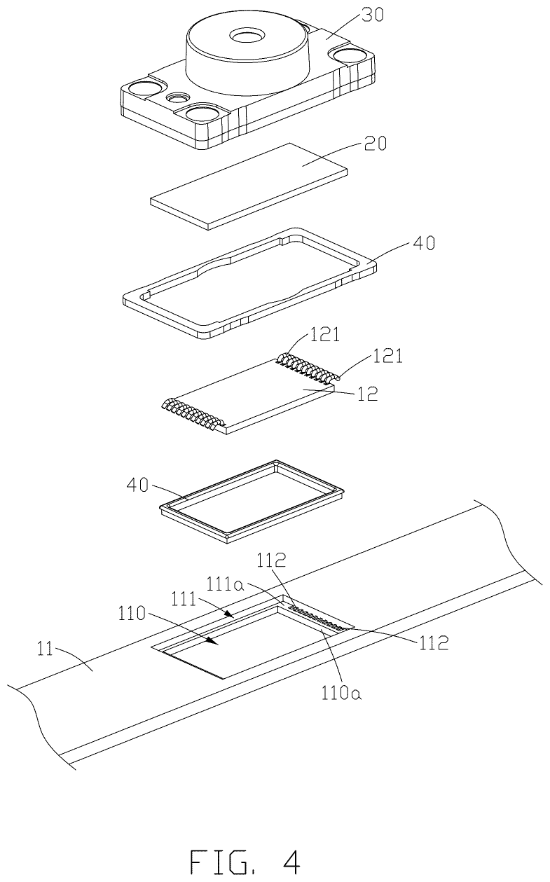

Referring to FIG. 4, the circuit board assembly 10 includes a printed circuit board 11 and an image sensor 12. The image sensor 12 is configured to receive the light passing through the light filter 20 and generate a sensing electrical signal according to the light, and the sensing electrical signal is used to generate an image.

The printed circuit board 11 has a first surface 11a and a second surface 11b facing and spaced apart from the first surface 11a. The printed circuit board 11A defines a through hole 110, and the through hole 110 penetrates the first surface 11a and the second surface 11b. The image sensor 12 is accommodated in the through hole 110, fixed on the printed circuit board 11, and electrically connected to the printed circuit board 11.

The printed circuit board 11 defines a groove 111 on the first surface 11a thereof, the groove 111 is located on at least one side of the through hole 110, and the groove 111 is in communication with the through hole 110. The image sensor 12 is provided with a plurality of first pins 121 at its side edge. A plurality of second pins 112 are provided in the groove 111. The plurality of second pins 112 are provided on a bottom wall 111a of the groove 111. The plurality of first pins 121 are respectively electrically connected to the plurality of second pins 112 via a plurality of wires 13, such that the image sensor 12 is electrically connected to the printed circuit board 11. The wires 13 are lower than the first surface 11a, that is, the entire wires 13 are contained in the groove 111. The opening of the through hole 110 is larger than the image sensor 12, so that the entire image sensor 12 can be accommodated in the through hole 110, and there is a gap between a side surface of the image sensor 12 and an inner wall 110a of the through hole 110. An adhesive 40 is filled between the side surface of the image sensor 12 and the inner wall 110a to fix the side surface of the image sensor 12 to the inner wall 110a of the through hole 110, so that the image sensor 12 is fixed to the printed circuit board 11. The groove 111 is designed to sink the second pins 112 of the printed circuit board 11 for electrically connecting to the image sensor 12, so that the wires 13 electrically connecting the printed circuit board 11 and the image sensor 12 can be sunk into the printed circuit board 11, thereby saving space for the circuit board assembly 10 and the camera module 100. Therefore, thicknesses of the circuit board assembly 10 and the camera module 100 can be reduced. A position of the groove 111 is determined according to a position of the first pins 121 on the image sensor 12. In the embodiment shown in FIG. 4, the first pins 121 are disposed at side edges of two opposite sides of the image sensor 12. Accordingly, the groove 111 is defined on both sides of the through hole 110 corresponding to the first pins 121 of the image sensor 12, and the second pins 112 are disposed on both sides of the through hole 110 corresponding to the first pins 121 of the image sensor 12. In other embodiments, when the first pins 121 is disposed only at an side edge of one side of the image sensor 12, the groove 111 is defined only on the side of the through hole 110 corresponding to the first pins 121 of the image sensor 12, and the second pins 112 are disposed only on the side of the through hole 110 corresponding to the first pins 121 of the image sensor 12. When the first pins 121 for connecting to the printed circuit board 11 are disposed at side edge of each side of the image sensor 12, the groove 111 is defined on each side of the through hole 110, the second pins 112 are disposed on each side of the through hole 110, that is, the groove 111 surrounds a periphery of the through hole 10, and the second pins 112 surround the periphery of the through hole 10.

The light filter 20 covers the entire image sensor 12 and the entire through hole 110, and is fixedly connected to the first surface 11a of the printed circuit board 11. The light filter 20 is spaced apart from the image sensor 12 and the wires 13. The lens assembly 30 covers the side of the light filter 20 facing away from the image sensor 12, and is fixedly connected to the first surface 11a of the printed circuit board 11. In the embodiment, an orthographic projection of the light filter 20 on the printed circuit board 11 completely covers the entire image sensor 12, and an orthographic projection of the lens assembly 30 on the printed circuit board 11 covers the entire light filter 20, so that light incident from the lens assembly 30 can reach the light filter 2, then pass through the light filter 2, and then be received by the image sensor 1.

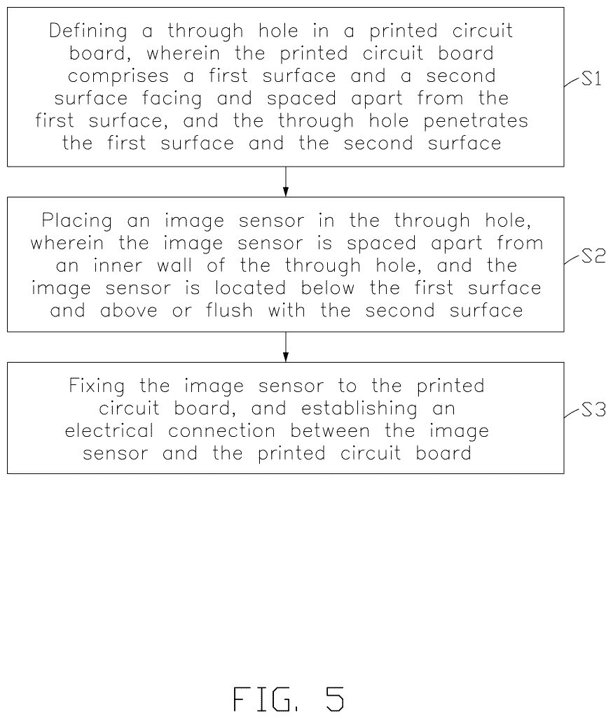

Referring to FIG. 3 to FIG. 5, the present disclosure provides a method of manufacturing the circuit board assembly 10, and the method includes the following steps.
S1: defining the through hole 110 in the printed circuit board 11. Wherein, the printed circuit board 11 includes the first surface 11a and the second surface 11b facing and spaced apart from the first surface 11a, and the through hole 110 penetrates the first surface 11a and the second surface 11b.
S2: placing the image sensor 12 in the through hole 110. Wherein, the image sensor 12 is spaced apart from the inner wall 111 of the through hole 110, and the image sensor 12 is lower than the first surface 11a and higher than or flush with the second surface 11b.
S3: fixing the image sensor 12 to the printed circuit board 11, and establishing an electrical connection between the image sensor 12 and the printed circuit board 11.

In step S1, the groove 111 is defined on the first surface 11a of the printed circuit board 11, the groove 111 being located on a side of the through hole 110, and the groove 111 being in direct communication with the through hole 110.

In step S2, the step of placing the image sensor 12 in the through hole 110 includes coating a Teflon coating layer on a die bonder 3, placing the printed circuit board 11 and the image sensor 12 on the die bonder 3, and fixing the printed circuit board 11 and the image sensor 12 by the die bonder 3.

When the Teflon coating layer is applied on the die bonder 3 to prevent the adhesive 40 from adhering to the die bonder 3 and the printed circuit board 11, the adhesive 40 adheres to the die bonder 3, making it difficult to remove the circuit board assembly 10 from the die bonder 3. In other embodiments, other types of materials, such as polyamide or polytetrafluoroethylene, may be applied on the die bonder 3.

Furthermore, the step of fixing the printed circuit board 11 and the image sensor 12 by the die bonder 3 includes: defining a plurality of vent holes 300, which are spaced apart from each other, on the die bonder 3; placing a vacuum pump in each vent 300, each vacuum pump being configured to adsorb the printed circuit board 11 and the image sensor 12.

In step S3, the image sensor 12 is spaced apart from the inner wall 111 of the through hole 110, so that there is a gap between the side surface of the image sensor 12 and the inner wall 111.

A method of fixing the image sensor 12 to the printed circuit board 11 includes filling the adhesive 40 between the side surface of the image sensor 12 and the inner wall 111 to fix the image sensor 12 to the inner wall 111 of the through hole 110, wherein the adhesive 40 surrounds the image sensor 12. The adhesive 40 can be quick-drying glue.

Steps of establishing the electrical connection between the image sensor 12 and the printed circuit board 11 includes forming the plurality of first pins 121 at edges of the image sensor 12, forming the plurality of second pins 121 on the bottom wall 111a of the groove 111, and electrically connecting the plurality of first pins 121 and the plurality of second pins 112 via the plurality of wires 13, wherein the wires 13 are lower than the first surface 11a, so that the entire wires 13 are located in the groove 111.

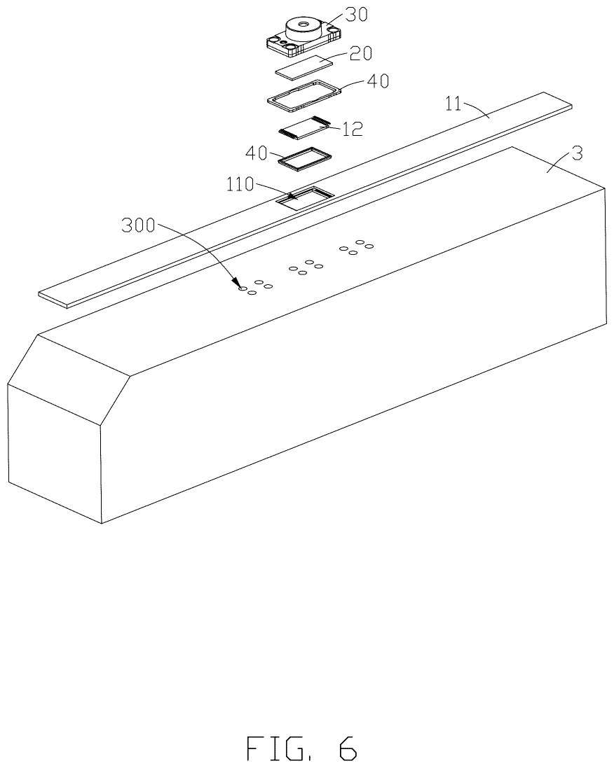

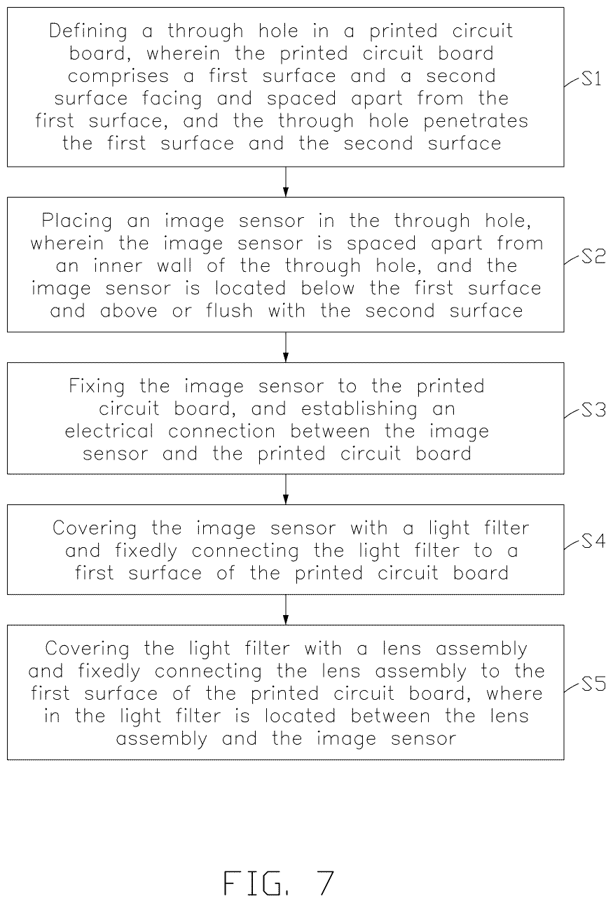

Referring to FIG. 6 and FIG. 7, the present disclosure provides a packaging method of the camera module 100. The packaging method includes the following steps.
S1: defining the through hole 110 in the printed circuit board 11. Wherein, the printed circuit board 11 includes the first surface 11a and the second surface 11b facing and spaced apart from the first surface 11a, and the through hole 110 penetrates the first surface 11a and the second surface 11b.
S2: placing the image sensor 12 in the through hole 110. Wherein, the image sensor 12 is spaced apart from the inner wall 111 of the through hole 110, and the image sensor 12 is lower than the first surface 11a and higher than or flush with the second surface 11b.
S3: fixing the image sensor 12 to the printed circuit board 11, and establishing an electrical connection between the image sensor 12 and the printed circuit board 11.
S4: covering the image sensor 12 with the light filter 20 and fixedly connecting the light filter 20 to the first surface 11a of the printed circuit board 11.
S5: covering the light filter 20 with the lens assembly 30 and fixing connecting the lens assembly 30 to the first surface 11a of the printed circuit board 11. Wherein, the light filter 20 is located between the lens assembly 30 and the image sensor 12.

In step S4, after covering the image sensor 12 with the light filter 20 and fixedly connecting the light filter 20 to the first surface 11a of the printed circuit board 11, since the wires 13 are lower than the first surface 11a, the light filter 20 is spaced apart from the wires 13, so that the light filter 20 can be directly attached to the first surface 11a of the printed circuit board 11.

In step S5, the adhesive 40 is formed between the lens assembly 30 and the first surface 11a to fix the lens assembly 30 to the first surface 11a of the printed circuit board 11. Wherein, the adhesive 40 can be quick-drying glue.

In a comparative example, the circuit board assembly includes a printed circuit board and an image sensor which is directly disposed on one surface of the printed circuit board and is electrically connected to the printed circuit board. Thus, in such a comparative example, a total thickness of the circuit board assembly is a sum of a thickness of the printed circuit board and a thickness of the image sensor.

In the manufacturing method of the circuit board assembly 10, the packaging method of the camera module 100, the circuit board assembly 10, the camera module 100 and the electronic device 1 of the present application, the through hole 110 penetrating the first surface 11a and the second surface 11b is defined in the printed circuit board 11, the image sensor 12 is disposed in the through hole 110, and the image sensor 12 is lower than the first surface 11a, that is, the entire image sensor 12 is accommodated in the through hole 110, so that the image sensor 12 does not occupy extra space in the thickness direction, and the overall thickness of the circuit board assembly 10 is equivalent to the thickness of the printed circuit board 11. Therefore, compared with the above comparative example, the present disclosure can effectively reduce the total thickness of the circuit board assembly 10.

Furthermore, the groove 111 defined on the first surface 11a of the printed circuit board 11 is located on at least one side of the through hole 110, the plurality of second pins 112 are disposed on the bottom wall 111a of the groove 111, the plurality of first pins 121 are disposed on the image sensor 12, and the plurality of first pins 121 are connected to the plurality of second pins 112 via wires 13. The wires 13 are lower than the first surface 11a of the printed circuit board 11, so that the entire wires 13 are located in the groove 111, and the wires 13 do not occupy extra space in the thickness direction of the circuit board assembly 10. Therefore, the light filter 20 can be directly mounted at the through hole 110 and adhered to the first surface 11a of the printed circuit board 11, thereby reducing the height of the camera module 100.

In conclusion, in the manufacturing method of the circuit board assembly 10, the packaging method of camera module 100, the circuit board assembly 10, the camera module 100 and the electronic device 1 of the present disclosure, a height of the camera module 100 is reduced without changing the size of existing components, thereby reducing the size of the camera module 100 and making the electronic device 1 including the camera module 100 thinner and lighter.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure as defined by the appended claims.

What is claimed is:

1. A method of manufacturing a circuit board assembly, the method comprising:
defining a through hole penetrating a first surface and a second surface of a printed circuit board, the first surface and the second surface facing each other and spaced apart;
placing an image sensor in the through hole, wherein the image sensor is spaced apart from an inner wall of the through hole, and the image sensor is lower than the first surface and higher than or flush with the second surface; and
fixing the image sensor to the printed circuit board, and establishing an electrical connection between the image sensor and the printed circuit board.

2. The method of claim 1, further comprising defining a groove on the first surface, wherein the groove is located on a side of the through hole, and the groove is in direct communication with the through hole;
establishing the electrical connection between the image sensor and the printed circuit board comprises:
forming a plurality of first pins at an edge of the image sensor,
forming a plurality of second pins on a bottom wall of the groove, and
electrically connecting the plurality of first pins and the plurality of second pins via a plurality of wires, wherein the plurality of wires is below the first surface.

3. The method of claim 1, wherein fixing the image sensor to the printed circuit board comprises:
filling an adhesive between a side surface of the image sensor and the inner wall of the through hole, wherein the adhesive surrounds the image sensor.

4. The method of claim 1, wherein placing the image sensor in the through hole comprises:
coating a Teflon coating layer on a die bonder,
placing the printed circuit board and the image sensor on the die bonder, and
fixing the printed circuit board and the image sensor by the die bonder.

5. The method of claim 4, wherein fixing the printed circuit board and the image sensor by the die bonder comprises:
defining a plurality of vent holes which are spaced apart from each other on the die bonder;
placing a vacuum pump in each of the plurality of vent holes, wherein the vacuum pump is configured to absorb the printed circuit board and the image sensor.

6. A packaging method of a camera module, the packaging method comprising:
defining a through hole in a printed circuit board;
placing an image sensor in the through hole;
fixing the image sensor to the printed circuit board, and establishing an electrical connection between the image sensor and the printed circuit board;
covering the image sensor with a light filter and fixedly connecting the light filter to a first surface of the printed circuit board; and
covering the light filter with a lens assembly and fixedly connecting the lens assembly to the first surface of the printed circuit board, wherein the light filter is located between the lens assembly and the image sensor.

7. The packaging method of claim 6, wherein fixing the lens assembly to the first surface of the printed circuit board comprises:
forming an adhesive between the lens assembly and the first surface.

8. The packaging method of claim 6, further comprising defining a groove on the first surface, wherein the groove is located on a side of the through hole, and the groove is in direct communication with the through hole;
establishing the electrical connection between the image sensor and the printed circuit board comprises:
forming a plurality of first pins at an edge of the image sensor,
forming a plurality of second pins on a bottom wall of the groove, and
electrically connecting the plurality of first pins and the plurality of second pins via a plurality of wires, wherein the plurality of wires is below the first surface.

9. The packaging method of claim 6, wherein fixing the image sensor to the printed circuit board comprises:
filling an adhesive between a side surface of the image sensor and an inner wall of the through hole, wherein the adhesive surrounds the image sensor.

10. The method of claim 6, wherein placing the image sensor in the through hole comprises:
coating a Teflon coating layer on a die bonder,
placing the printed circuit board and the image sensor on the die bonder, and
fixing the printed circuit board and the image sensor by the die bonder.

11. The method of claim 10, wherein fixing the printed circuit board and the image sensor by the die bonder comprises:
defining a plurality of vent holes which are spaced apart from each other on the die bonder;
placing a vacuum pump in each of the plurality of vent holes, wherein the vacuum pump is configured to absorb the printed circuit board and the image sensor.

12. A circuit board assembly, comprising:
a printed circuit board comprising a first surface and a second surface facing each other and spaced apart, the printed circuit board defining a through hole penetrating the first surface and the second surface;
an image sensor in the through hole and fixed to and electrically connected to the printed circuit board, wherein the image sensor is spaced apart from an inner wall of the through hole, and the image sensor is lower than the first surface and higher than or flush with the second surface.

13. The circuit board assembly of claim 12, wherein the first surface defines a groove on at least one side of the through hole, the groove is in direct communication with the through hole, a plurality of first pins is disposed at an edge of the image sensor, a plurality of second is disposed on a bottom wall of the groove, the plurality of first pins is electrically connected to the plurality of second pins via a plurality of wires, and the plurality of wires is below the first surface.

14. The circuit board assembly of claim 12, further comprising an adhesive filling between a side surface of the image sensor and the inner wall of the through hole.

15. A camera module comprising:
the circuit board assembly of claim 12;
a light filter covering the image sensor and fixedly connected to the first surface;
wherein the lens assembly is configured to receive and transmit external light, the light filter is located on an optical path of light emitted by the lens assembly and is configured to filter out part of the light, the image sensor is configured to receive the other part of the light and generate an image according to the other part of light.

16. The camera module of claim 15, wherein the first surface defines a groove on at least one side of the through hole, the groove is in direct communication with the through hole, a plurality of first pins is disposed at an edge of the image sensor, a plurality of second is disposed on a bottom wall of the groove, the plurality of first pins is electrically connected to the plurality of second pins via a plurality of wires, and the plurality of wires is below the first surface.

17. The circuit board assembly of claim 15, further comprising an adhesive filling between a side surface of the image sensor and the inner wall of the through hole.

18. An electronic device comprising:
the camera module of claim 15; and
a display module electrically connected to the printed circuit board and configured to display an image generated by the camera module.
